(19) United States
(12) Patent Application Publication
(10) Pub. No.: US 2024/0164172 A1
(43) Pub. Date: May 16, 2024

(54) LIGHT-EMITTING DEVICE

(71) Applicant: Unique Materials Co., Ltd., Taipei City (TW)

(72) Inventors: Huan-Wei Tseng, Taipei City (TW); Chun-Wei Chou, Taipei City (TW); Chia-Chun Liao, Taipei City (TW)

(73) Assignee: Unique Materials Co., Ltd., Taipei City (TW)

(21) Appl. No.: 18/499,247

(22) Filed: Nov. 1, 2023

Related U.S. Application Data
(60) Provisional application No. 63/422,004, filed on Nov. 3, 2022.

(30) Foreign Application Priority Data
Oct. 3, 2023 (TW) 112137920

(51) Int. Cl. H10K 59/38; H10K 59/80

(52) U.S. Cl. CPC H10K 59/38; H10K 59/8731; H10K 2102/331

(57) ABSTRACT

Provided is a light-emitting device including a substrate, a first light-emitting unit, a second light-emitting unit, a third light-emitting unit, a blue light absorbing photoresist layer and an atomic layer deposition (ALD) gas barrier layer. The first light-emitting unit includes a first micro LED device and a first light conversion layer wrapping the first micro LED device, the second light-emitting unit includes a second micro LED device and a second light conversion layer wrapping the second micro LED device, and the third light-emitting unit includes a third micro LED device and the third light conversion layer wrapping the third micro LED device. The blue light absorbing photoresist layer covers the first and second light-emitting units, while exposing the third light-emitting unit. The ALD gas barrier layer wraps the first, second, and third light-emitting units, and the blue light absorbing photoresist layer.

### CROSS-REFERENCE TO RELATED APPLICATIONS

This application claims the priority benefits of U.S. provisional application Ser. No. 63/422,004 filed on Nov. 3, 2022 and Taiwan application serial no. 112137920, filed on Oct. 3, 2023. The entirety of each of the above-mentioned patent applications is hereby incorporated by reference herein and made a part of this specification.

### BACKGROUND OF THE INVENTION

### Field of the Invention

The invention relates to a light-emitting device with a micro light-emitting diode (micro LED) device.

### Description of Related Art

Currently, micro LED displays with quantum dots commonly have problems such as low product reliability, short lifetime, or the like. Additionally, since the quantum dots cannot completely convert all blue light into red or green light, a red or green filter is needed to filter out the excess blue light that is not converted by the quantum dots while allowing the desired red or green light to pass through. However, the red or green light transmittance of the color filters is usually less than 80%. In this case, the available red or green light will also decrease due to the color filter, thereby reducing the performance of the light-emitting device.

Some current technologies, such as distributed Bragg reflector (DBR), can reflect the blue light back to the quantum dots layer to increase the overall conversion rate of the blue light. However, DBR or other similar optical components will allow more undesired blue light to pass through the filter, and DBR is more expensive and difficult to manufacture.

### SUMMARY OF THE INVENTION

The invention provides a light-emitting device including a substrate, a first light-emitting unit, a second light-emitting unit, a third light-emitting unit, a blue light absorbing photoresist layer, and an atomic layer deposition (ALD) gas barrier layer. The first light-emitting unit, the second light-emitting unit, and the third light-emitting unit are disposed on the substrate. The first light-emitting unit includes a first micro light-emitting diode (micro LED) device and a first light conversion layer wrapping the first micro LED device. The second light-emitting unit includes a second micro LED device and a second light conversion layer wrapping the second micro LED device. The third light-emitting unit includes a third micro LED device and the third light conversion layer wrapping the third micro LED device. The first, second, and third light-emitting units emit light of different colors. The blue light absorbing photoresist layer covers the first and second light-emitting units, while exposing the third light-emitting unit. The ALD gas barrier layer wraps the first, second, and third light-emitting units, and the blue light absorbing photoresist layer.

The invention provides a light-emitting device including a first tier and a second tier. The first tier includes a plurality of blue light-emitting units disposed on a first substrate. The second tier is disposed on the first tier. The second tier includes a first light-emitting unit, corresponding to a first portion of the plurality of blue light-emitting units, wherein the first light-emitting unit comprises a first light conversion layer and a first blue light absorbing photoresist layer covering the first light conversion layer; a second light-emitting unit, corresponding to a second portion of the plurality of blue light-emitting units, wherein the second light-emitting unit comprises a second light conversion layer and a second blue light absorbing photoresist layer covering the second light conversion layer; a third light-emitting unit, corresponding to a third portion of the plurality of blue light-emitting units, wherein the third light-emitting unit comprises a third light conversion layer and does not have any blue light absorbing photoresist layer; a second substrate, covering the first, second, and third light-emitting units; and an ALD gas barrier layer wrapping the first, second, and third light-emitting units, and the second substrate.

Based on the above, in the present invention, the blue light absorbing photoresist layer covers a red light-emitting unit and a green light-emitting unit, while exposing a blue light-emitting unit. In this case, the blue light absorbing photoresist layer can effectively absorb the excess blue light that is not converted by the red or green quantum dots, while allowing more red or green light to pass through. As such, the light-emitting device of the present invention can increase the color saturation, thereby improving the display performance and providing the wider color gamut.

### BRIEF DESCRIPTION OF THE DRAWINGS

FIG. 1 is a schematic cross-sectional view of a light-emitting device according to an embodiment of the invention.

FIG. 2 is a flow chart of a method for forming a light-emitting device according to an embodiment of the invention.

FIG. 3 is a schematic top view of a light-emitting device according to an embodiment of the invention.

FIG. 4 is a schematic cross-sectional view of a light-emitting device according to alternative embodiments of the invention.

FIG. 5A is a schematic cross-sectional view of a gas barrier layer of a light-emitting device according to an embodiment of the invention.

FIG. 5B is a schematic cross-sectional view of a gas barrier layer of a light-emitting device according to another embodiment of the invention.

FIG. 6 is a schematic cross-sectional view of a gas barrier layer of a light-emitting device according to others embodiments of the invention.

### DETAILED DESCRIPTION OF DISCLOSED EMBODIMENTS

The invention is illustrated more comprehensively referring to the drawings of the embodiments. However, the invention may be embodied in many different forms and should not be construed as limited to the embodiments set forth herein. Thicknesses of layers and regions in the drawings may be enlarged for clarity. The same or similar reference numerals represent the same or similar components, and are not repeated in the following paragraphs.

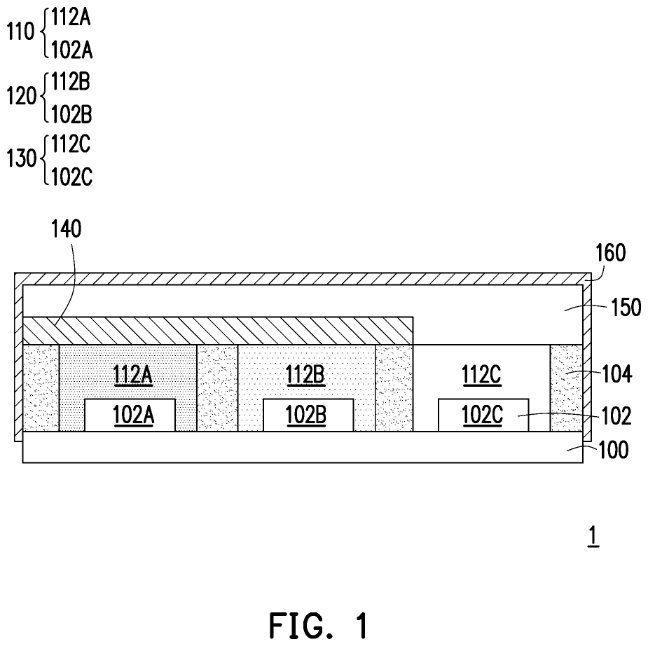

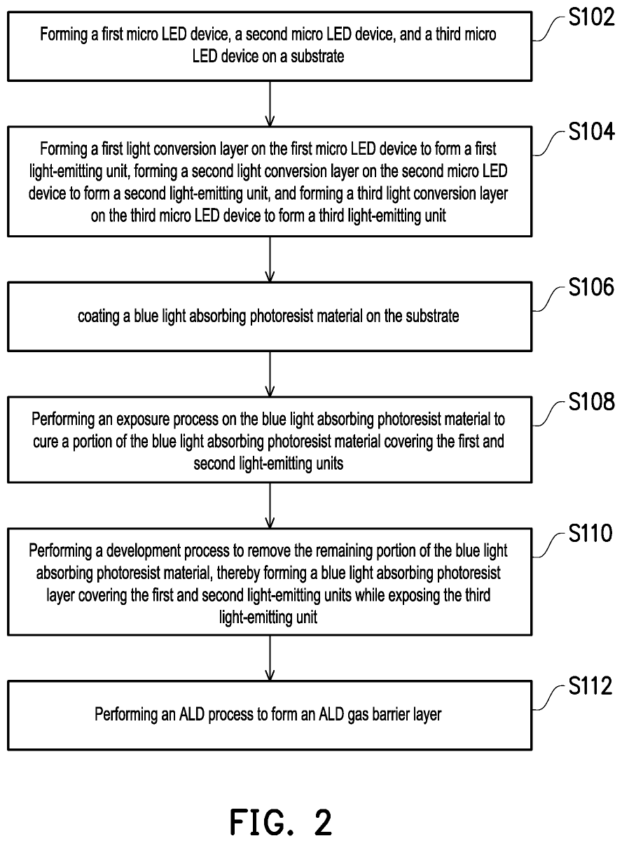

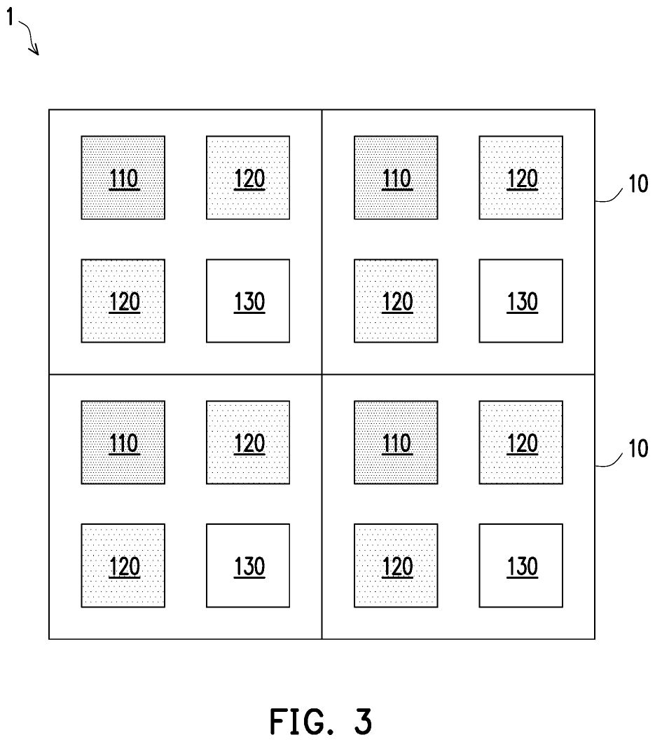

FIG. 1 is a schematic cross-sectional view of a light-emitting device according to an embodiment of the invention. FIG. 2 is a flow chart of a method for forming a light-emitting device according to an embodiment of the invention. FIG. 3 is a schematic top view of a light-emitting device according to an embodiment of the invention.

Referring to FIG. 1, in an embodiment of the present invention, a light-emitting device 1 includes a substrate 100, a first light-emitting unit 110, a second light-emitting unit 120, a third light-emitting unit 130, a blue light absorbing photoresist layer 140, and an atomic layer deposition (ALD) gas barrier layer 160. In one embodiment, the substrate 100 may be a glass substrate, a polymer substrate, a composite substrate with conductive metal lines therein, or the like.

Specifically, the first light-emitting unit 110, the second light-emitting unit 120, and the third light-emitting unit 130 may be disposed on the substrate 100. In one embodiment, the first light-emitting unit 110 includes a first micro LED device 102A and a first light conversion layer 112A wrapping the first micro LED device 102A; the second light-emitting unit 120 includes a second micro LED device 102B and a second light conversion layer 112B wrapping the second micro LED device 102B; and the third light-emitting unit 130 includes a third micro LED device 102C and a third light conversion layer 112C wrapping the third micro LED device 102C. The first light-emitting unit 110, the second light-emitting unit 120, and the third light-emitting unit 130 may emit light of different colors. For example, the first light-emitting unit 110 may emit red light, the second light-emitting unit 120 may emit green light, and the third light-emitting unit 130 may emit blue light. In the embodiment, the first light-emitting unit 110 may be regarded as a red light-emitting unit, the second light-emitting unit 120 may be regarded as a green light-emitting unit, and the third light-emitting unit 130 may be regarded as a blue light-emitting unit. In the present embodiment, the light-emitting device 1 further includes a black matrix 104 disposed between the first light-emitting unit 110, the second light-emitting unit 120, and the third light-emitting unit 130 to prevent light from being transmitted between the first light-emitting unit 110, the second light-emitting unit 120, and the third light-emitting unit 130.

As shown in FIG. 2, a method of forming the first light-emitting unit 110, the second light-emitting unit 120, and the third light-emitting unit 130 includes the following steps. First, a step S102 is performed to form the first micro LED device 102A, the second micro LED device 102B, and the third micro LED device 102C on the substrate 100. In the embodiment, all of the first micro LED device 102A, the second micro LED device 102B and the third micro LED device 102C are blue light micro LED devices (may be collectively referred to as blue light micro LED devices 102), and may emit blue light with a wavelength of approximately 450 nm, for example. Next, a step S104 is performed. The first light conversion layer 112A is formed on the first micro LED device 102A to form the first light-emitting unit 110; the second light conversion layer 112B is formed on the second micro LED device 102B to form the second light-emitting unit 120; and a third light conversion layer 112C is formed on the third micro LED device 102C to form a third light-emitting unit 130. In one embodiment, the blue micro LED devices 102 may be inorganic-based micro LED devices, organic-based micro OLED devices or quantum-dot-based micro QLED devices.

Specifically, the step of forming the first light-emitting unit 110 may include: coating a red quantum-dot photoresist material on the substrate 100. In one embodiment, the red quantum-dot photoresist material includes red quantum dots uniformly dispersed in a photoresist material. A first exposure process is performed on the red quantum-dot photoresist material to cure a portion of the red quantum-dot photoresist material covering the first micro LED device 102A. In one embodiment, the first exposure process may irradiate light on a portion of the red quantum-dot photoresist material covering the first micro LED device 102A, while not irradiating light on other portions of the red quantum-dot photoresist material covering the second micro LED device 102B and the third micro LED device 102C. That is, the other portions of the red quantum-dot photoresist material covering the second micro LED device 102B and the third micro LED device 102C is not cured. A first development process is then performed to remove the remaining portion of the red quantum-dot photoresist material (i.e., the unirradiated portion), thereby forming the first light conversion layer 112A (hereinafter referred to as the red quantum-dot photoresist layer 112A). In the embodiment, the red quantum-dot photoresist layer 112A covers the first micro LED device 102A while exposes the second micro LED device 102B and the third micro LED device 102C. In addition, a pre-bake step may be performed before the first exposure process, and a post-bake step may be performed after the first development process.

Similarly, the step of forming the second light-emitting unit 120 may include: coating a green quantum-dot photoresist material on the substrate 100; performing a second exposure process on the green quantum-dot photoresist material to cure a portion of the green quantum-dot photoresist material covering the second micro LED device 102B; and performing a second development process to remove the remaining portion of the green quantum-dot photoresist material, thereby forming a second light conversion layer 112B (hereinafter referred to as the green quantum-dot photoresist layer 112B) covering the second micro LED device 102B while exposing the third micro LED device 102C. In one embodiment, the green quantum-dot photoresist material includes green quantum dots uniformly dispersed in a photoresist material.

Similarly, the step of forming the third light-emitting unit 130 may include: coating a white photoresist material on the substrate 100; performing a third exposure process on the white photoresist material to cure a portion of the white photoresist material covering the third micro LED device 102C; and performing a third development process to remove the remaining portion of the white photoresist material, thereby forming a third light conversion layer 112C (hereinafter referred to as the white photoresist layer 112C) covering the third micro LED device 102C. In one embodiment, the white photoresist layer 112C does not contain quantum dots. In one embodiment, the white photoresist layer may include light scattering particles, such as silicon dioxide, titanium dioxide, aluminum oxide, zirconium dioxide, or a combination thereof. In this case, the white photoresist layer 112C can make the blue light emitted from the third micro LED device 102C more uniform.

Although the above embodiment is described in the order of forming the first light-emitting unit 110, the second light-emitting unit 120, and the third light-emitting unit 130, the present invention is not limited thereto. In other embodiments, the first light-emitting unit 110, the second light-emitting unit 120, and the third light-emitting unit 130 may also be formed in different orders. That is, for example, the first light-emitting unit 110 and the third light-emitting unit 130 may be formed after forming the second light-emitting unit 120.

After forming the first light-emitting unit 110, the second light-emitting unit 120, and the third light-emitting unit 130, as shown in FIG. 2, a step S106 is performed to coat a blue light absorbing photoresist material on the substrate 100 to cover the first light-emitting unit 110, the second light-emitting unit 120, and the third light-emitting unit 130. In one embodiment, the blue light absorbing photoresist material includes cadmium sulfide, lead chromate, bismuth vanadate, Pigment Yellow 181, Pigment Yellow 191, or a combination thereof, and may be formed by spin coating. The blue light absorbing photoresist material can absorb more than 99% of the blue light with a wavelength of about 450 nm, and have the red light and green light transmittance of more than 90%.

Next, a step S108 is performed. An exposure process on the blue light absorbing photoresist material is performed to cure a portion of the blue light absorbing photoresist material covering the first light-emitting unit 110 and the second light-emitting unit 120. In one embodiment, the exposure process may irradiate light on a portion of the blue light absorbing photoresist material covering the first light-emitting unit 110 and the second light-emitting unit 120, while not irradiate light on other portions of the blue light absorbing photoresist material covering the third light-emitting unit 130. That is, the other portions of the blue light absorbing photoresist material covering the third light-emitting unit 130 is not cured.

Then, a step S110 is performed. A development process is performed to remove the remaining portion of the blue light absorbing photoresist material, thereby forming a blue light absorbing photoresist layer 140 covering the first light-emitting unit 110 and the second light-emitting unit 120 while exposing the third light-emitting unit 130, as shown in FIG. 1. That is, the blue light absorbing photoresist layer 140 covers the red light-emitting unit 110 and the green light-emitting unit 120, while exposes the blue light-emitting unit 130. In this case, the blue light absorbing photoresist layer 140 can effectively absorb excess blue light that is not converted by the red or green quantum dots, while allowing more red or green light to pass through. In the embodiment, the blue light absorbing photoresist layer 140 can absorb more than 99% of the blue light with the wavelength of about 450 nm, and have the red light or green light transmittance of more than 90%. Compared with conventional color filters with the red light or green light transmittance of about 70% to 80%, the light-emitting device 1 of the present embodiment can effectively improve the red or green light transmittance while enhancing the color saturation, thereby improving the display performance and providing the wider color gamut. In addition, a pre-bake step may be performed before the exposure process, and a post-bake step may be performed after the development process.

After forming the blue light absorbing photoresist layer 140, a planarization layer 150 may be formed on the substrate 100. In one embodiment, the planarization layer 150 covers the blue light absorbing photoresist layer 140 and extends to cover the third light-emitting unit 130 and a portion of the black matrix 104. In the embodiment, the planarization layer 150 may be a transparent resin layer so that the light emitted by the first light-emitting unit 110, the second light-emitting unit 120, and the third light-emitting unit 130 may pass through the transparent resin layer. In addition, the planarization layer 150 may even out the top surface of the light-emitting device 1, which facilitates the subsequent formation of the ALD gas barrier layer 160.

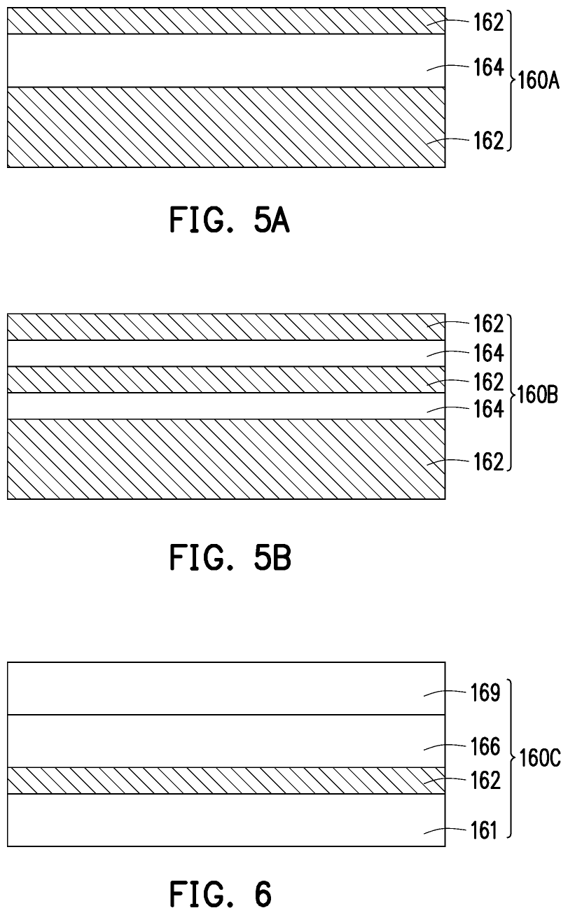

Referring back to FIG. 2, after forming the planarization layer 150, a step S112 is performed. An atomic layer deposition (ALD) process is performed to form an ALD gas barrier layer 160 wrapping the first light-emitting unit 110, the second light-emitting unit 120, the third light-emitting unit 130, and the blue light absorbing photoresist layer 140. Specifically, the ALD gas barrier layer 160 may cover the sidewall of the black matrix 104 laterally encapsulating the first light-emitting unit 110, the second light-emitting unit 120, and the third light-emitting unit 130; the sidewall of the blue light absorbing photoresist layer 140; and the sidewall of the planarization layer 150, and the top surface of planarization layer 150. The ALD gas barrier layer 160 can effectively block the external environmental factors such as moisture, oxygen, volatile substances and others to improve the reliability and the lifetime of the light-emitting device 1 of the present embodiment. In one embodiment, the ALD gas barrier layer 160 includes a single-layered structure, a bi-layered structure, or a multi-layered structure. For example, in one embodiment, the ALD gas barrier layer 160A is a three-layered structure composed of aluminum oxide 162/silicon dioxide 164/aluminum oxide 162, as shown in FIG. 5A. In another embodiment, the ALD gas barrier layer 160B is a five-layered structure composed of aluminum oxide 162/silicon dioxide 164/aluminum oxide 162/silicon dioxide 164/aluminum oxide 162, as shown in FIG. 5B. The aluminum oxide layer 162 can effectively block the external environmental factors such as moisture, oxygen, or the like due to its high density. The silicon dioxide layer 164 is relatively flexible and may be used as a buffer layer to release the stress of the aluminum oxide layer 162 and prevent the aluminum oxide layer 162 from cracking. In another embodiment, silicon dioxide 164 may be replaced with zinc oxide, zirconium dioxide, titanium dioxide, or hafnium dioxide. The thickness of the aluminum oxide 162 and the silicon dioxide 164 may be adjusted according to actual needs, and the embodiment of the present invention does not limit the thickness range.

In alternative embodiments, referring to FIG. 6, an ALD gas barrier layer 160C includes a single layer of aluminum oxide 162 which is wrapped by organic protective layers 161, 169 and a plasma-enhanced chemical vapor deposition (PECVD) gas barrier layer 166, so as to form a four-layered structure composed of the first organic protective layer 161/aluminum oxide 162/the PECVD gas barrier layer 166/the second organic protective layer 169. The first organic protective layer 161 and the second organic protective layer 169 may sandwich the aluminum oxide layer 162 and the PECVD gas barrier layer 166 therebetween to prevent the aluminum oxide layer 162 and the PECVD gas barrier layer 166 from cracking due to their highly brittle nature, and improves the adhesion between the ALD gas barrier layer 160C and the structure/layer contacting the ALD gas barrier layer 160C. The aluminum oxide layer 162 and the PECVD gas barrier layer 166 can effectively block the external environmental factors such as moisture, oxygen, or the like due to their high density. Further, the process of forming the PECVD gas barrier layer 166 requires ion bombardment, and the aluminum oxide 162 can effectively protect the quantum-dot photoresist layer and prevent the quantum dots from being damaged by the ion bombardment. That is, the aluminum oxide 162 may be closer to the quantum-dot photoresist layers 112A and 112B (FIG. 1) than the PECVD gas barrier layer 166 to prevent the quantum dots from being damaged by the ion bombardment. The first organic protective layer 161 and the second organic protective layer 169 may each include photo-curable or thermo-curable acrylic resin, epoxy resin, or silicone resin. In one embodiment, the first organic protective layer 161 and the second organic protective layer 169 may have the same material. In other embodiments, the first organic protective layer 161 and the second organic protective layer 169 may have different materials. The PECVD gas barrier layer 166 may include silicon nitride (SiNₓ) or silicon oxynitride (SiOₓN_{y}). The thicknesses of the first organic protective layer 161, the aluminum oxide 162, the PECVD gas barrier layer 166, and the second organic protective layer 169 may be adjusted according to actual needs, and the embodiment of the present invention does not limit the thickness range.

Referring to FIG. 3, the first light-emitting unit 110, the second light-emitting unit 120 and, the third light-emitting unit 130 may be arranged into a pixel 10. A plurality of pixels 10 may be arranged into an array of a plurality of rows and a plurality of columns. In one embodiment, each pixel 10 has a single first light-emitting unit 110, two second light-emitting units 120 and a single third light-emitting unit 130, and are arranged in a 2×2 array, but the invention is not limited thereto. In other embodiments, each pixel 10 may have any number of light-emitting units and may be arranged in any manner.

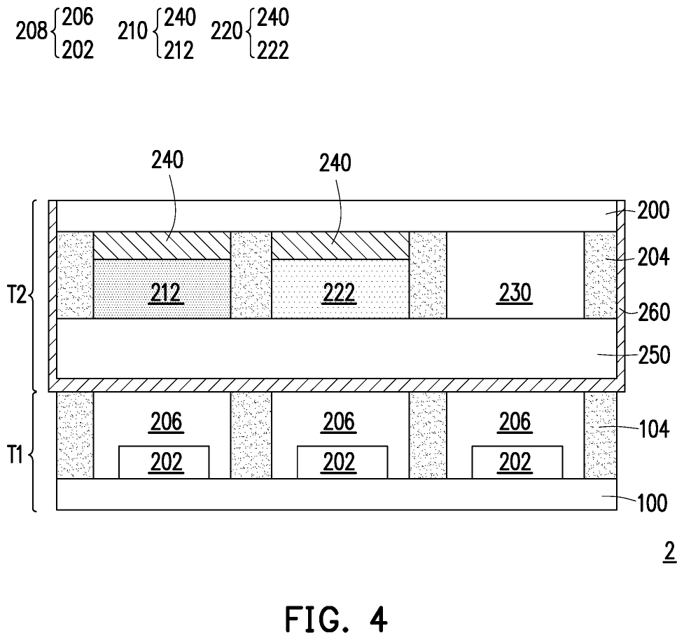

FIG. 4 is a schematic cross-sectional view of a light-emitting device according to alternative embodiments of the invention.

Referring to FIG. 4, in alternative embodiments of the present invention, a light-emitting device 2 includes: a first tier T1 and a second tier T2. Specifically, the first tier T1 includes a plurality of blue light-emitting units 208 disposed on a first substrate 100. In one embodiment, each light-emitting unit 208 includes a blue micro LED device 202 and a transparent photoresist material 206 wrapping the blue micro LED device 202. In one embodiment, the blue micro LED device 202 may be an inorganic-based micro LED device, an organic-based micro OLED device or a quantum-dot-based micro QLED device. In addition, the first tier T1 further includes a black matrix 104 disposed between the light-emitting units 208 to prevent light from being transmitted between the light-emitting units 208.

The second tier T2 may be disposed on the first tier T1. Specifically, the second tier T2 includes a first light-emitting unit 210, a second light-emitting unit 220, and a third light-emitting unit 230. In one embodiment, the first light-emitting unit 210 corresponds to a first portion of the blue light-emitting unit 208. The first light-emitting unit 210 may include a first light conversion layer 212 and a blue light absorbing photoresist layer 240 covering the first light conversion layer 212. In one embodiment, the second light-emitting unit 220 corresponds to a second portion of the blue light-emitting unit 208. The second light-emitting unit 220 may include a second light conversion layer 222 and a blue light absorbing photoresist layer 240 covering the second light conversion layer 222. In one embodiment, the third light-emitting unit 230 corresponds to a third portion of the blue light-emitting unit 208. The third light-emitting unit 230 may include a third light conversion layer and does not have any blue light absorbing photoresist layer. In one embodiment, the third light conversion layer may be a white photoresist layer including light scattering particles (e.g., silicon dioxide, titanium dioxide, aluminum oxide, zirconium dioxide, or a combination thereof). The first light-emitting unit 210, the second light-emitting unit 220, and the third light-emitting unit 230 may emit light of different colors. For example, the first light conversion layer 212 may be a red quantum-dot photoresist layer so that the first light-emitting unit 210 emits red light after being excited by blue light; the second light conversion layer 222 may be a green quantum-dot photoresist layer so that the second light-emitting unit 220 emits green light after being excited by blue light; and the third light-emitting unit 230 may be a third light conversion layer so that the light-emitting unit 208 uniformly emits blue light through the third light conversion layer. It should be noted that, in the present embodiment, the red light-emitting unit 210 and the green light-emitting unit 220 have the blue light absorbing photoresist layer 240, while the blue light-emitting unit 230 does not have the blue light absorbing photoresist layer 240. In this case, the blue light absorbing photoresist layer 240 can effectively absorb the excess blue light that is not converted by the red or green quantum dots, while allowing more red or green light to pass through. In the present embodiment, the blue light absorbing photoresist layer 240 can absorb more than 99% of the blue light with the wavelength of about 450 nm, and have the red light or green light transmittance of more than 90%. Compared with the conventional color filters with the red light or green light transmittance of about 70% to 80%, the light-emitting device 2 of the present embodiment can effectively improve the red or green light transmittance while enhancing the color saturation, thereby improving the display performance and providing the wider color gamut.

In addition, the light-emitting device 2 further includes a black matrix 204, a second substrate 200, a planarization layer 250 and, an ALD gas barrier layer 260. The black matrix 204 may be disposed between the first light-emitting unit 210, the second light-emitting unit 220, and the third light-emitting unit 230 to prevent light from being transmitted between the first light-emitting unit 210, the second light-emitting unit 220, and the third light-emitting unit 230. The second substrate 200 may be disposed on the black matrix 204 and extend to cover the first light-emitting unit 210, the second light-emitting unit 220, and the third light-emitting unit 230. The planarization layer 250 may be disposed between the ALD gas barrier layer 260 and the first light-emitting unit 210, between the ALD gas barrier layer 260 and the second light-emitting unit 220, and between the ALD gas barrier layer 260 and the third light-emitting unit 230. The ALD gas barrier layer 260 may wrap the first light-emitting unit 210, the second light-emitting unit 220, the third light-emitting unit 230, the planarization layer 250, and the second substrate 200. Specifically, the ALD gas barrier layer 260 may cover the sidewall of the second substrate 200; the sidewall of the black matrix 204 laterally encapsulating the first light-emitting unit 210, the second light-emitting unit 220 and the third light-emitting unit 230; and the sidewall and the bottom surface of the planarization layer 250. That is, the ALD gas barrier layer 260 may extend between the top surface of the first tier T1 and the bottom surface of the second tier T2. In the embodiment, the ALD gas barrier layer 260 can effectively block the external environmental factors such as moisture, oxygen, volatile substances and others to improve the reliability and the lifetime of the light-emitting device 2 of the present embodiment.

It should be noted that the size (e.g., width or length) of the blue light-emitting diode device 202 selected for the light-emitting device 2 may be smaller than the size of the blue-light micro LED device 102 selected for the light-emitting device 1. In one embodiment, the size of the blue micro LED device 202 is about 10 μm to about 15 μm, and the size of the blue light micro LED device 102 is about 50 μm. In this case, the light-emitting device 2 is suitable for a small-size display with a higher resolution, while the light-emitting device 1 is suitable for a large-size display.

In summary, in the present invention, the blue light absorbing photoresist layer covers the red light-emitting unit and the green light-emitting unit, while exposing the blue light-emitting unit. In this case, the blue light absorbing photoresist layer can effectively absorb the excess blue light that is not converted by the red or green quantum dots, while allowing more red or green light to pass through. As such, the light-emitting device of the present invention can increase the color saturation, thereby improving the display performance and providing the wider color gamut.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A light-emitting device, comprising:
a substrate;
a first light-emitting unit, a second light-emitting unit, and a third light-emitting unit disposed on the substrate, wherein the first light-emitting unit comprises a first micro light-emitting diode (micro LED) device and a first light conversion layer wrapping the first micro LED device, the second light-emitting unit comprises a second micro LED device and a second light conversion layer wrapping the second micro LED device, and the third light-emitting unit comprises a third micro LED device and the third light conversion layer wrapping the third micro LED device, and the first, second, and third light-emitting units emit light of different colors; and
a blue light absorbing photoresist layer covering the first and second light-emitting units, while exposing the third light-emitting unit.

2. The light-emitting device of claim 1, wherein the first, second and third micro LED devices are inorganic-based micro LED devices, organic-based micro OLED devices or quantum-dot-based micro QLED devices.

3. The light-emitting device of claim 1, wherein the first light-emitting unit emits red light, the second light-emitting unit emits green light, and the third light-emitting unit emits blue light.

4. The light-emitting device of claim 3, wherein the first light conversion layer comprises a red quantum-dot photoresist layer, the second light conversion layer comprises a green quantum-dot photoresist layer, and the third light conversion layer comprises a white photoresist layer without any quantum dot.

5. The light-emitting device of claim 1, further comprising: an atomic layer deposition (ALD) gas barrier layer wrapping the first, second, and third light-emitting units, and the blue light absorbing photoresist layer.

6. The light-emitting device of claim 5, further comprising:
a black matrix, disposed between the first, second, and third light-emitting units; and
a planarization layer, disposed between the ALD gas barrier layer and the blue light absorbing photoresist layer and extending to cover the third light emitting unit and the black matrix.

7. The light-emitting device of claim 5, wherein the ALD gas barrier layer comprises a three-layered structure composed of aluminum oxide/silicon dioxide/aluminum oxide.

8. The light-emitting device of claim 5, wherein the ALD gas barrier layer comprises a five-layered structure composed of aluminum oxide/silicon dioxide/aluminum oxide/silicon dioxide/aluminum oxide.

9. The light-emitting device of claim 7, wherein the silicon dioxide in the ALD gas barrier layer can be replaced by zinc oxide, zirconium dioxide, titanium dioxide, or hafnium dioxide.

10. The light-emitting device of claim 5, wherein the ALD gas barrier layer comprises aluminum oxide which is wrapped by an organic protective layer and a plasma-enhanced chemical vapor deposition (PECVD) gas barrier layer, so as to form a four-layered structure composed of a first organic protective layer/aluminum oxide/the PECVD gas barrier layer/a second organic protective layer.

11. The light-emitting device of claim 10, wherein the first and second organic protective layers each comprises photo-curable or thermo-curable acrylic resin, epoxy resin, or silicone resin.

12. The light-emitting device of claim 10, wherein the PECVD gas barrier layer comprises silicon nitride (SiNₓ) or silicon oxynitride (SiOₓN_{y}).

13. The light-emitting device of claim 1, wherein a material of the blue light absorbing photoresist layer comprises cadmium sulfide, lead chromate, bismuth vanadate, Pigment Yellow 181, Pigment Yellow 191, or a combination thereof.

14. A light-emitting device, comprising:
a first tier, comprises a plurality of blue light-emitting units disposed on a first substrate; and
a second tier, disposed on the first tier, wherein the second tier comprises:
a first light-emitting unit, corresponding to a first portion of the plurality of blue light-emitting units, wherein the first light-emitting unit comprises a first light conversion layer and a first blue light absorbing photoresist layer covering the first light conversion layer;
a second light-emitting unit, corresponding to a second portion of the plurality of blue light-emitting units, wherein the second light-emitting unit comprises a second light conversion layer and a second blue light absorbing photoresist layer covering the second light conversion layer;
a third light-emitting unit, corresponding to a third portion of the plurality of blue light-emitting units, wherein the third light-emitting unit comprises a third light conversion layer and does not have any blue light absorbing photoresist layer; and
a second substrate, covering the first, second, and third light-emitting units.

15. The light-emitting device of claim 14, further comprising: an ALD gas barrier layer wrapping the first, second, and third light-emitting units, and the second substrate.

16. The light-emitting device of claim 15, wherein the ALD gas barrier layer further extends between a top surface of the first tier and a bottom surface of the second tier.

17. The light-emitting device of claim 14, wherein each blue light-emitting unit comprises a blue light micro LED device and a transparent photoresist material wrapping the blue light micro LED device, wherein the blue light micro LED device is an inorganic-based micro LED device, an organic-based micro OLED device or a quantum-dot-based micro QLED device.

18. The light-emitting device of claim 14, wherein the first light-emitting unit emits red light, the second light-emitting unit emits green light, and the third light-emitting unit emits blue light.

19. The light-emitting device of claim 14, wherein the first light conversion layer comprises a red quantum-dot photoresist layer, the second light conversion layer comprises a green quantum-dot photoresist layer, and the third light conversion layer comprises a white photoresist layer without any quantum dot.

20. The light-emitting device of claim 15, further comprising:
a black matrix, disposed between the first, second, and third light-emitting units; and
a planarization layer, disposed between the ALD gas barrier layer and the first light-emitting unit, between the ALD gas barrier layer and the second light-emitting unit, and between the ALD gas barrier layer and the third light-emitting unit.

21. The light-emitting device of claim 15, wherein the ALD gas barrier layer comprises a three-layered structure composed of aluminum oxide/silicon dioxide/aluminum oxide.

22. The light-emitting device of claim 15, wherein the ALD gas barrier layer comprises a five-layered structure composed of aluminum oxide/silicon dioxide/aluminum oxide/silicon dioxide/aluminum oxide.

23. The light-emitting device of claim 21, wherein the silicon dioxide in the ALD gas barrier layer can be replaced by zinc oxide, zirconium dioxide, titanium dioxide, or hafnium dioxide.

24. The light-emitting device of claim 15, wherein the ALD gas barrier layer comprises aluminum oxide which is wrapped by an organic protective layer and a plasma-enhanced chemical vapor deposition (PECVD) gas barrier layer, so as to form a four-layered structure composed of a first organic protective layer/aluminum oxide/the PECVD gas barrier layer/a second organic protective layer.

25. The light-emitting device of claim 24, wherein the first and second organic protective layers each comprises photo-curable or thermo-curable acrylic resin, epoxy resin, or silicone resin.

26. The light-emitting device of claim 24, wherein the PECVD gas barrier layer comprises silicon nitride (SiNₓ) or silicon oxynitride (SiOₓN_{y}).

27. The light-emitting device of claim 14, wherein a material of the blue light absorbing photoresist layer comprises cadmium sulfide, lead chromate, bismuth vanadate, Pigment Yellow 181, Pigment Yellow 191, or a combination thereof.
